(19) United States
(12) Patent Application Publication
(10) Pub. No.: US 2025/0093900 A1
(43) Pub. Date: Mar. 20, 2025

(54) SYSTEMS AND METHODS FOR ELECTRONIC FUSE MANAGEMENT

(71) Applicant: QUALCOMM Incorporated, San Diego, CA (US)

(72) Inventor: Remi GERAUD-STEWART, Mantes-la-Jolie (FR)

(21) Appl. No.: 18/467,234

(22) Filed: Sep. 14, 2023

(51) Int. Cl. G05F 3/10; H03K 19/21; H03M 13/00; H03M 13/15

(52) U.S. Cl. CPC G05F 3/10; H03M 13/1575; H03M 13/611; H03K 19/21

(57) ABSTRACT

Disclosed are electronic fuse management systems and techniques. For instance, an electronic fuse management system is described. The electronic fuse management system receives an indication of a value to be written to a plurality of electronic fuses. The system combines the value with a codeword to determine a pattern for the plurality of electronic fuses. The codeword is based on a previous pattern of the plurality of electronic fuses. In some examples, the system processes the previous pattern with a codeword function (e.g., a non-systematic Hamming codeword function) to generate the codeword. In some examples the system determines an exclusive or (XOR) of the value and the codeword to combine the value with the codeword. The system sets (e.g., writes to) a subset of the plurality of electronic fuses according to the pattern.

### FIELD

The present disclosure generally relates to electronic fuse management. For example, aspects of the present disclosure relate to systems and techniques for managing a set of electronic fuses to allow the set of electronic fuses to encode multiple different values at different times.

### BACKGROUND

Electronic fuses are current-sensitive devices that can be modified by running current through them. In some examples, when current is run through an electronic fuse, a portion of the electronic fuse is physically destroyed and cannot easily be repaired, thus modifying (e.g., destructively and/or irreversibly) the electronic fuse. An electronic fuse that has not been modified in this way can be referred to intact, while an electronic fuse that has been modified in this way can be referred to blown. In some examples, an electronic fuse encodes a Boolean value, in that the electronic fuse is either intact or blown.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary presents certain concepts relating to one or more aspects relating to the mechanisms disclosed herein in a simplified form to precede the detailed description presented below.

Disclosed are systems, methods, apparatuses, and computer-readable media for electronic fuse management. For instance, an electronic fuse management system is described. The electronic fuse management system receives an indication of a value to be written to a plurality of electronic fuses. The system combines the value with a codeword to determine a pattern for the plurality of electronic fuses. The codeword is based on a previous pattern of the plurality of electronic fuses. In some examples, the system processes the previous pattern with a codeword function (e.g., a non-systematic Hamming codeword function) to generate the codeword. In some examples the system determines an exclusive or (XOR) of the value and the codeword to combine the value with the codeword. The system sets (e.g., writes to) a subset of the plurality of electronic fuses according to the pattern.

According to at least one example, an apparatus for electronic fuse management is provided. The apparatus includes a memory and at least one processor (e.g., implemented in circuitry) coupled to the memory. The at least one processor is configured to and can: receive an indication of a value to be written to a plurality of electronic fuses; combine the value with a codeword to determine a pattern for the plurality of electronic fuses, the codeword based on a previous pattern of the plurality of electronic fuses; and set a subset of the plurality of electronic fuses according to the pattern.

In another example, a method for wireless communications is provided. The method comprises: receiving an indication of a value to be written to a plurality of electronic fuses; determining a pattern for the plurality of electronic fuses based on combining the value with a codeword, the codeword based on a previous pattern of the plurality of electronic fuses; and setting a subset of the plurality of electronic fuses according to the pattern.

As another example, a non-transitory computer-readable medium is provided having stored thereon instructions that, when executed by at least one processor, cause the at least one processor to: receive an indication of a value to be written to a plurality of electronic fuses; combine the value with a codeword to determine a pattern for the plurality of electronic fuses, the codeword based on a previous pattern of the plurality of electronic fuses; and set a subset of the plurality of electronic fuses according to the pattern.

In another example, an apparatus for wireless communications is provided. The apparatus comprises: means for receiving an indication of a value to be written to a plurality of electronic fuses; means for determining a pattern for the plurality of electronic fuses based on combining the value with a codeword, the codeword based on a previous pattern of the plurality of electronic fuses; and means for setting a subset of the plurality of electronic fuses according to the pattern.

In some aspects, one or more of the apparatuses described herein is, is a part of, or includes a mobile device (e.g., a mobile telephone or so-called “smart phone”, a tablet computer, or other type of mobile device), a wearable device, an extended reality device (e.g., a virtual reality (VR) device, an augmented reality (AR) device, or a mixed reality (MR) device), a personal computer, a laptop computer, a video server, a television (e.g., a network-connected television), a vehicle (or a computing device or system of a vehicle), or other device. In some aspects, the apparatus includes at least one camera for capturing one or more images or video frames. For example, the apparatus can include a camera (e.g., an RGB camera) or multiple cameras for capturing one or more images and/or one or more videos including video frames. In some aspects, the apparatus includes a display for displaying one or more images, videos, notifications, or other displayable data. In some aspects, the apparatus includes a transmitter configured to transmit one or more video frame and/or syntax data over a transmission medium to at least one device. In some aspects, the processor includes a neural processing unit (NPU), a central processing unit (CPU), a graphics processing unit (GPU), or other processing device or component.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages, will be better understood from the following description when considered in connection with the accompanying figures. Each of the figures is provided for the purposes of illustration and description, and not as a definition of the limits of the claims.

While aspects are described in the present disclosure by illustration to some examples, those skilled in the art will understand that such aspects may be implemented in many different arrangements and scenarios. Techniques described herein may be implemented using different platform types, devices, systems, shapes, sizes, and/or packaging arrangements. For example, some aspects may be implemented via integrated chip embodiments or other non-module-component based devices (e.g., end-user devices, vehicles, communication devices, computing devices, industrial equipment, retail/purchasing devices, medical devices, and/or artificial intelligence devices). Aspects may be implemented in chip-level components, modular components, non-modular components, non-chip-level components, device-level components, and/or system-level components. Devices incorporating described aspects and features may include additional components and features for implementation and practice of claimed and described aspects. For example, transmission and reception of wireless signals may include one or more components for analog and digital purposes (e.g., hardware components including antennas, radio frequency (RF) chains, power amplifiers, modulators, buffers, processors, interleavers, adders, and/or summers). It is intended that aspects described herein may be practiced in a wide variety of devices, components, systems, distributed arrangements, and/or end-user devices of varying size, shape, and constitution.

Other objects and advantages associated with the aspects disclosed herein will be apparent to those skilled in the art based on the accompanying drawings and detailed description.

### BRIEF DESCRIPTION OF THE DRAWINGS

Examples of various implementations are described in detail below with reference to the following figures:

FIG. 1 is a block diagram illustrating an example of a computing system with an electronic fuse management subsystem, in accordance with some examples;

FIG. 2 is a block diagram illustrating a process for electronic fuse management using an electronic fuse management system, in accordance with some examples;

FIG. 3 is a conceptual diagram illustrating a process in which different values x₁-x₄ are represented in an electronic fuse set using patterns y₁-y₄ at times t₁-t₄, and a calculation for calculating the pattern y₄ based on the pattern y₃ and the value x₄, in accordance with some examples;

FIG. 4 is a conceptual diagram illustrating a process of writing multiple values to an electronic fuse set to permanently write a value x₄ to the electronic fuse set based on a request, in accordance with some examples;

FIG. 5 is a flow diagram illustrating an example of a process for electronic fuse management, in accordance with aspects of the present disclosure;

FIG. 6 is a diagram illustrating an example of a computing system, according to aspects of the disclosure.

### DETAILED DESCRIPTION

Certain aspects and embodiments of this disclosure are provided below. Some of these aspects and embodiments may be applied independently and some of them may be applied in combination as would be apparent to those of skill in the art. In the following description, for the purposes of explanation, specific details are set forth in order to provide a thorough understanding of embodiments of the application. However, it will be apparent that various embodiments may be practiced without these specific details. The figures and description are not intended to be restrictive.

The ensuing description provides example embodiments only, and is not intended to limit the scope, applicability, or configuration of the disclosure. Rather, the ensuing description of the exemplary embodiments will provide those skilled in the art with an enabling description for implementing an exemplary embodiment. It should be understood that various changes may be made in the function and arrangement of elements without departing from the spirit and scope of the application as set forth in the appended claims.

Systems, apparatuses, electronic devices, methods (also referred to as processes), and computer-readable media (collectively referred to herein as “systems and techniques”) are described herein for electronic fuse management. For instance, an electronic fuse management system is described. The electronic fuse management system receives an indication of a value to be written to a plurality of electronic fuses. The system combines the value with a codeword to determine a pattern for the plurality of electronic fuses. The codeword is based on a previous pattern of the plurality of electronic fuses. In some examples, the system processes the previous pattern with a codeword function (e.g., a non-systematic Hamming codeword function) to generate the codeword. In some examples the system determines an exclusive or (XOR) of the value and the codeword to combine the value with the codeword. The system sets (e.g., writes to) a subset of the plurality of electronic fuses according to the pattern.

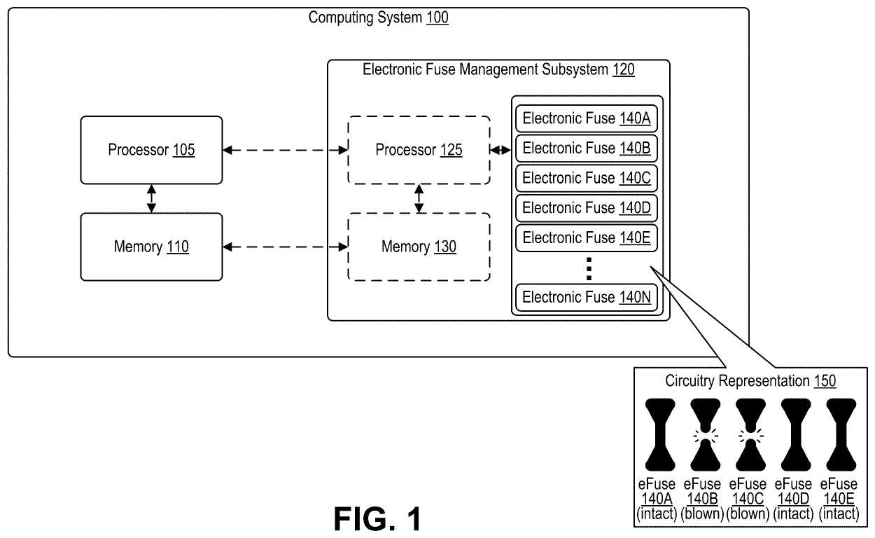

FIG. 1 is a block diagram illustrating an example of a computing system 100 with an electronic fuse management subsystem 120. The computing system 100 includes a processor 105, which may be an example of the processor 610. The computing system 100 includes a memory 110, which may be an example of the cache 612, the memory 615, the read-only memory (ROM) 620, the random access memory (RAM) 625, the storage device 630, or a combination thereof.

The computing system 100 includes an electronic fuse management subsystem 120. In some examples, the electronic fuse management subsystem 120 includes an associated processor 125, which may be an example of the processor 610. In some examples, the electronic fuse management subsystem 120 includes an associated memory 130, which may be an example of the cache 612, the memory 615, the read-only memory (ROM) 620, the random access memory (RAM) 625, the storage device 630, or a combination thereof.

The electronic fuse management subsystem 120 of the computing system 100 includes a set of electronic fuses 140A-140N, including at least an electronic fuse 140A, an electronic fuse 140B, an electronic fuse 140C, an electronic fuse 140D, an electronic fuse 140E, to an electronic fuse 140N. Electronic fuses can be referred to as eFuses. The set of electronic fuses 140A-140N can be referred to as an electronic fuse set, an electronic fuse circuit, an electronic fuse array, an eFuse set, an eFuse circuit, an eFuse array, a fuse set, a fuse circuit, a fuse array, or a combination thereof. The electronic fuses 140A-140N are current-sensitive devices that can be modified by running current (e.g., exceeding a threshold voltage) through them. In some examples, when current is run through an electronic fuse, a portion of the electronic fuse is physically destroyed and cannot easily be repaired, thus modifying (e.g., destructively and/or irreversibly) the electronic fuse. An electronic fuse that has not been modified in this way can be referred to intact or not blown. An electronic fuse that has been modified in this way can be referred to blown or no longer intact. In some examples, an electronic fuse encodes a Boolean value, in that the electronic fuse is either intact or blown. As discussed further herein, an intact fuse can represent the value zero (0), while a blown fuse can represent the value one (1).

A circuitry representation 150 of examples the electronic fuses 140A-140E is also illustrated in FIG. 1. In the circuitry representation 150, the electronic fuse 140A is illustrated as intact, the electronic fuses 140B-140C are illustrated as blown, and the electronic fuses 140D-140E are illustrated as intact. The electronic fuses 140A-140E illustrated in the examples of the circuitry representation 150 thus encode the value 01100.

In some examples, the processor 125 of the electronic fuse management subsystem 120 can execute an instruction that causes current to run through a specific subset of the set of electronic fuses 140A-140N to blow the specific subset of the electronic fuses 140A-140N. In some examples, the processor 105 of the computing system 100 can execute an instruction that causes current to run through a specific subset of the set of electronic fuses 140A-140N to blow the specific subset the set of electronic fuses 140A-140N. In some examples, the processor 105 of the computing system 100 can execute an instruction that requests the processor 125 of the electronic fuse management subsystem 120 to execute another instruction, that in turn causes current to run through a specific subset of the set of electronic fuses 140A-140N to blow the specific subset the set of electronic fuses 140A-140N. In an illustrative example, the processor 105 and/or the processor 125 can execute one or more instructions that cause current to run through the electronic fuses 140B-140C to modify the electronic fuses 140B-140C from an intact state to a blown state, as illustrated in the circuitry representation 150. In some examples, a processor (e.g., the processor 105 and/or the processor 125) executing instruction(s) to cause current to run through a subset of the electronic fuses 140A-140N to blow the subset of the electronic fuses 140A-140N can be referred to as writing to the subset of the electronic fuses 140A-140N, writing a value to the subset of the electronic fuses 140A-140N, setting the subset of the electronic fuses 140A-140N to a value, setting the subset of the electronic fuses 140A-140N according to a pattern, or a combination thereof.

In some examples, a specific subset of the electronic fuses 140A-140N can be blown to represent a value, such as a number, a letter, an alphanumeric value, a symbol, or another type of value. For instance, in an illustrative example, the computing system 100 can blow a subset of the electronic fuses 140A-140N in a pattern equivalent to a binary representation of a certain number, thus encoding that number. For instance, zero can represent zero, one can represent one, 10 can represent two, 11 can represent three, 100 can represent four, 101 can represent five, 111 can represent six, and so forth. However, blowing electronic fuses in such a pattern can make it difficult, if not impossible, to write to (to set) the set of electronic fuses again, since blown fuses generally cannot be repaired or restored to an intact state, and writing another value immediately after the first value can cause an issue in that it can be unclear where one value ends and the other begins. For instance, attempting to write a value of 2 (“10”) after writing a value of 3 (“11”) as “1110” can be unclear, as this binary representation could instead represent a value of 14 (“1110”) or even a value of 6 (“111”).

In some examples, electronic fuses can be used in a computing system 100 to identify information that is not expected to change, or that is not expected to change more than a threshold number of times. Because most computing systems (such as the computing system 100) that have electronic fuses only have a limited number of electronic fuses, such computing systems are generally limited to only being able to write values to the set of electronic fuses once, or a limited number of times (e.g., 2, 3, 4, or 5). For instance, in some examples, the computing system 100 can use the set of electronic fuses 140A-140N to encode a value representing a version (e.g., version number) of a program that runs on the computing system 100 (e.g., an operating system, a firmware, a Basic Input/Output System (BIOS), or an application), a hardware version (e.g., version number) or revision (e.g., revision number) of the computing system 100 (and/or of the electronic fuse management subsystem 120 and/or another component of the computing system 100), a cryptographic key (e.g., to be used for encryption and/or decryption), or a combination thereof. In some examples, one or more of these values can be written or set in the set of electronic fuses 140A-140N during manufacturing of the computing system 100.

In some examples, a new value representing a new cryptographic key should be written to the set of electronic fuses 140A-140N if the old cryptographic key is compromised and the new cryptographic key should be used instead. In some examples, a new value representing a new program version should be written to the set of electronic fuses 140A-140N if the program has been updated from an old version to the new version. In some examples, a new value representing a new hardware version or revision should be written to the set of electronic fuses 140A-140N if the computing system 100 is sent in for a repair and/or a hardware upgrade, and an older component corresponding to the old hardware version or revision is replaced with a newer component corresponding to the newer hardware version or revision.

In some examples, an intact fuse can instead represent the value one (1), while a blown fuse can represent the value zero (0). In some examples, an electronic fuse may be able to encode more than two values, for instance based on which portion of the electronic fuse is destructively modified or destructively set. Destructively setting an electronic fuse can refer to destroying a portion of the electronic fuse as part of modifying the electronic fuse. In some examples, an electronic fuse may be able to be repaired or otherwise reset to an intact state after being in a blown state, for instance through software, a hardware change or modification, or a combination thereof.

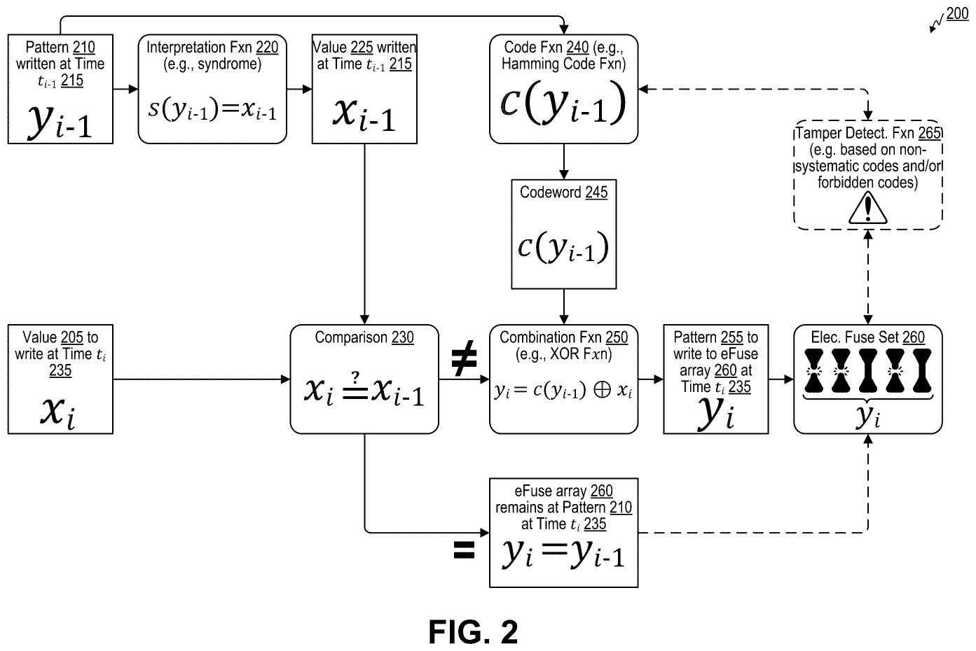

FIG. 2 is a block diagram illustrating a process 200 for electronic fuse management using an electronic fuse management system. The electronic fuse management system can include, for instance the computing system 100, the electronic fuse management subsystem 120, and/or the computing system 600. The electronic fuse management system that performs the process 200 includes an electronic fuse set 260, which is an example of the set of electronic fuses 140A-140N and/or the electronic fuse management subsystem 120. The electronic fuse management system that performs the process 200 includes one or more processors (e.g., processor 105, processor 125, processor 610) controllers, and/or other subsystems and/or components that execute various functions, such as an interpretation function 220, a comparison 230, a code function 240, and a combination function 250.

The electronic fuse management system receives, at a time tᵢ₋₁ 215 (or earlier), a value xᵢ 205 to be written to the electronic fuse set 260 at a time tᵢ 235. For instance, the electronic fuse management system can receive the value xᵢ 205 as part of a request to write the value xᵢ 205 to the electronic fuse set 260. At the time tᵢ₋₁ 215, the electronic fuse set 260 is set according to a pattern yᵢ₋₁ 210.

In some examples, the electronic fuse management system (or a subsystem thereof) interprets the pattern yᵢ₋₁ 210 using an interpretation function 220 to decode a value xᵢ₋₁ 225 encoded in the pattern yᵢ₋₁ 210 that is written to the electronic fuse set 260 at the time tᵢ₋₁ 215. Use of the interpretation function 220 to decode the value xᵢ₋₁ 225 from the pattern yᵢ₋₁ 210 is represented by Equation 1 below, with s( ) representing the interpretation function 220:

$$s ( {y}_{i - 1} ) = {x}_{ì - 1} \qquad Equation 1$$

In some examples, the electronic fuse management system (or a subsystem thereof) may have already stored the value xᵢ₋₁ 225, and thus can retrieve the stored value xᵢ₋₁ 225 without using the interpretation function 220 to decode the value xᵢ₋₁ 225 from the pattern yᵢ₋₁ 210. In some examples, the interpretation function 220 can be a syndrome. For instance, the electronic fuse management system (or a subsystem thereof) can compute the syndrome of the pattern yᵢ₋₁ 210 to determine the value xᵢ₋₁ 225. In some examples, computing the syndrome of the pattern yᵢ₋₁ 210 generates an invalid codeword that reveals the value xᵢ₋₁ 225.

The electronic fuse management system (or a subsystem thereof) performs a comparison 230 of the value xᵢ 205 to be written to the electronic fuse set 260 and the value xᵢ₋₁ 225 that is written (encoded in the pattern yᵢ₋₁ 210) in the electronic fuse set 260. If the comparison 230 finds that the value xᵢ 205 is equivalent to the value xᵢ₋₁ 225, then electronic fuse set 260 is to remain set according to the pattern yᵢ₋₁ 210. In other words, if the comparison 230 finds that the value xᵢ 205 is equivalent to the value xᵢ₋₁ 225, then a pattern yᵢ for the electronic fuse set 260 to be set to at the time tᵢ 235 is equivalent to the pattern yᵢ₋₁ 210, meaning that no change to the electronic fuse set 260 is made at the time tᵢ 235. In some examples, the electronic fuse management system (or a subsystem thereof) can send a signal to the electronic fuse set 260 to instruct the electronic fuse set 260 not to change from the pattern yᵢ₋₁ 210 to any different pattern between time tᵢ 215 and time tᵢ 235. In some examples, the electronic fuse management system (or a subsystem thereof) can omit sending anything to the electronic fuse set 260, allowing the electronic fuse set 260 to remain unchanged at the pattern yᵢ₋₁ 210 between time tᵢ₋₁ 215 and time tᵢ 235.

If the comparison 230 finds that the value xᵢ 205 is not equivalent to the value xᵢ₋₁ 225, then electronic fuse management system (or a subsystem thereof) uses a combination function 250 to combine a codeword c(yᵢ₋₁) 245 with the value xᵢ 205 to generate a pattern yᵢ 255 for the electronic fuse set 260 to be set to at the time tᵢ 235. In an illustrative example, the combination function 250 is an exclusive or (XOR) function. In some examples, the combination function 250 can include an XOR function, an AND function, an OR function, and adder, an average, a maximum, a minimum, and/or another type of combination.

The electronic fuse management system (or a subsystem thereof) can use a code function 240 to generate the codeword c(yᵢ₋₁) 245 based on the pattern yᵢ₋₁ 210. In an illustrative example, the codeword c(yᵢ₋₁) 245 is a Hamming codeword (e.g., systematic Hamming codeword or non-systematic Hamming codeword), and the code function c( ) 240 is a Hamming codeword function (e.g., systematic Hamming codeword function or non-systematic Hamming codeword function). In some examples, the codeword c(yᵢ₋₁) 245 is a Hamming codeword, Sperner codeword (e.g., locking or non-locking), a Reed-Solomon codeword, a Goppa codeword, a Niederreiter codeword, a Reed-Muller codeword, a Steane codeword, a systematic codeword, a non-systematic codeword, or a combination thereof. In some examples, the code function c( ) 240 is a Hamming codeword function, a Sperner codeword function (e.g., locking or non-locking), a Reed-Solomon codeword function, a Goppa codeword function, a Niederreiter codeword function, a Reed-Muller codeword function, a Steane codeword function, a systematic codeword function, a non-systematic codeword function, or a combination thereof. Each of these codeword encoding techniques, applied to the pattern yᵢ₋₁ 210 and XORed to the value xᵢ 205, can ensure that once a bit flips from 0 to 1 (e.g., once the corresponding electronic fuse is modified from being intact to being blown), the bit does not flip back from 1 to 0 (e.g., thus not relying on a blown electronic fuse to be “repaired” into an intact state).

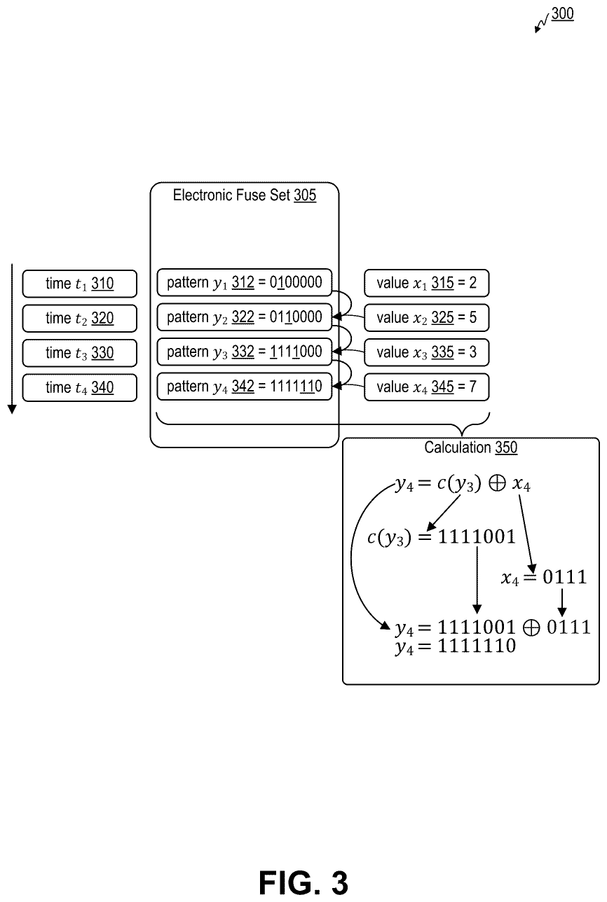

In an illustrative example, the code function c( ) 240 can generate [n, k, 3] Hamming codewords, where n indicates the number of electronic fuses in the electronic fuse set 260 and k indicates a number of bits in the successive values x (e.g., the value xᵢ 205, the value xᵢ₋₁ 225) to be written to the electronic fuse set 260 according to the patterns (e.g., pattern yᵢ₋₁ 210, pattern yᵢ 255) that are based on the codewords (e.g., codeword c(yᵢ₋₁) 245). In an illustrative example, the code function c( ) 240 as used in the calculation 350 of FIG. 3 can use [7, 4, 3] Hamming codewords. The electronic fuse set 305 of FIG. 3 has π electronic fuses (as indicated by the 7 digits in the patterns y₁-y₄), and thus n=7. In an illustrative example, k=4, and thus the values x₁-x₄ can be 4-bit values, in some cases allowing use of values between 0 (0000) and 16 (1111) for a given value xᵢ. In some examples, the code function c( ) 240 can generate a 7-bit codeword with one or more parity bits from a 4-bit value. In some examples, the code function c( ) 240 generates parity bits that overlap so that a single-bit error in a data bit or a parity bit can be detected and corrected.

In the context of the process 200, comparison 230, the use of the code function c( ) 240 to generate the codeword c(yᵢ₋₁) 245, and the use of the combination function 250 to generate the pattern yᵢ 255, are represented in Equation 2 below, with the combination function 250 represented using an XOR operator (⊕):

$${y}_{i} = \{ \begin{matrix}{y}_{i - 1} & if {x}_{i} = {x}_{i - 1} \\ c ( {y}_{i - 1} ) ⊕ {x}_{i} & otherwise\end{matrix} \qquad Equation 2$$

Once the electronic fuse management system (or a subsystem thereof) generates the pattern yᵢ 255, the electronic fuse management system (or a subsystem thereof) can identify a subset of the electronic fuses in the electronic fuse set 260 to send current (e.g., exceeding a threshold voltage) through to modify (e.g., destructively and/or irreversibly) in order to set the electronic fuse set 260 to the pattern yᵢ 255. The subset of the electronic fuse set 260 can be a difference between the pattern yᵢ₋₁ 210 and the pattern yᵢ 255. In an illustrative example, if the pattern yᵢ₋₁ 210 is 0110000 and the pattern yᵢ 255 is 1111000 (as in the pattern y₂ 322 and the pattern y₃ 332), then the subset can include the first and fourth electronic fuses from the left, which can be represented as 1001000.

In some examples, the electronic fuse management system can repeat the process 200 iteratively until the electronic fuse set 260 can no longer be written to. For instance, in a first iteration of the process 200, the electronic fuse management system can process the pattern yᵢ₋₁ 210 from a time tᵢ₋₁ 215 and the value xᵢ 205 to determine the pattern yᵢ 255 for a time tᵢ 235 as discussed above. In a second iteration of the process 200, the pattern yᵢ 255 determined in the first iteration of the process 200 can become the pattern yᵢ₋₁ 210 in the second iteration of the process 200, the value xᵢ 205 from the first iteration of the process 200 can become the value xᵢ₋₁ 225 in the second iteration of the process 200, and the time tᵢ 235 from the first iteration of the process 200 can become the time tᵢ₋₁ 215 in the second iteration of the process 200. The process can iterate similarly into a third iteration, a fourth iteration, a fifth iteration, and so forth, until the electronic fuse set 260 no longer has enough electronic fuses that remain intact to write a new value (e.g., as in the value xᵢ 205) to the electronic fuse set 260 by setting the electronic fuse set 260 to a new pattern (e.g., as in the pattern yᵢ 255).

In some examples, the electronic fuse management system (or a subsystem thereof) can use a tamper detection function 265 to detect tampering with the electronic fuse set 260, and/or to detect an attempt to tamper with the electronic fuse set 260. The tamper detection function 265 can be based on customization of the code function c( ) 240 to provide tamper-detectability to the codeword c(yᵢ₋₁) 245. Hamming codes exist for [2^{r}−1, 2^{r}−r−1,3] for all values of r. This allows for 2^{r}−r−1 possible writes to an electronic fuse set having 2^{r}−1 bits (e.g., 2^{r}−1 electronic fuses), to store r-bit values (e.g., r=3). In some examples, the electronic fuse management system (or a subsystem thereof) can store a cryptographic message authentication code (MAC), which the tamper detection function 265 can use to verify the validity of the value encoded in the pattern, and thus the pattern itself. However, storing a MAC along with the value itself requires a larger electronic fuse set 260 to provide a strong security guarantee.

In some examples, the code function c( ) 240 can be configured to use non-systematic Hamming codewords (or other non-systematic codewords), and/or to avoid a set of forbidden data elements. Use of non-systematic Hamming codewords (or other non-systematic codewords) and corresponding non-systematic code functions for the code function c( ) 240 can prevent a malicious party from knowing which electronic fuses to blow to encode the value(s) that the malicious party wishes to encode in the electronic fuse set 260, since non-systematic code constructions cannot necessarily begin with their inputs or be otherwise easily converted back into their inputs (e.g., the pattern yᵢ₋₁ 210). Use of forbidden data elements, especially in combination with non-systematic code functions (e.g., non-systematic Hamming code functions), can provide a detection mechanism. Forbidden data elements can include, for instance, forbidden codewords (e.g., forbidden values for the codeword c(yᵢ₋₁) 245), forbidden values (e.g., forbidden values for the value xᵢ 205 and/or the value xᵢ₋₁ 225), and/or forbidden patterns (e.g., forbidden values for the pattern yᵢ 255 and/or the pattern yᵢ₋₁ 210). If the tamper detection function 265 detects that the electronic fuse set 260 is set to a forbidden pattern, the tamper detection function 265 can determine that the electronic fuse set 260 has been tampered with, or that an error has occurred (e.g., one or more of the electronic fuses has blown due to an error such as a power surge or a software bug). If the tamper detection function 265 detects that the pattern yᵢ 255 that the electronic fuse set 260 is set to is based on a codeword c(yᵢ₋₁) 245 that matches a forbidden codeword and/or a value xᵢ 205 that matches a forbidden value, the tamper detection function 265 can determine that the electronic fuse set 260 has been tampered with, or that an error has occurred. The tamper detection function 265 can also be referred to as an error detection function 265.

In some examples, detection of tampering (or of an error) can cause the computing system that includes the electronic fuse set 260 (e.g., the computing system 100 and/or the electronic fuse management subsystem 120) to be permanently locked, for instance by causing a value indicative of tampering and/or error detection to be permanently written to the electronic fuse set 260 as illustrated and discussed with respect to the process 400 for permanent writing. Use of non-systematic code functions (e.g., non-systematic Hamming code functions) in combination with forbidden data elements can make it difficult for a malicious party to attempt to guess or brute-force their way into writing a given value. For instance, if half of the possible data elements (half of the possible patterns, codewords, and/or values) are forbidden, then modifying a fuse at random will result with 50% probability in the tampering being detected, and the electronic fuse set potentially being permanently locked.

FIG. 3 is a conceptual diagram illustrating a process 300 in which different values x₁-x₄ are represented in an electronic fuse set 305 using patterns y₁-y₄ at times t₁-t₄, and a calculation 350 for calculating the pattern y₄ 342 based on the pattern y₃ 332 and the value x₄ 345. The electronic fuse set 305 is an example of the electronic fuse set 260, the set of electronic fuses 140A-140N, the electronic fuse management subsystem 120, or a combination thereof. The patterns y₁-y₄ and values x₁-x₄ of the process 300 are organized according to the times t₁-t₄, with time moving forward from time t₁ 310, through time t₂ 320 and time t₃ 330, to time t₄ 340.

At time t₁ 310, the electronic fuse set 305 is set according to a pattern y₁ 312 that is identified as 0100000. The electronic fuse set 305 is a 7-bit electronic fuse set, indicated by the seven digits of the pattern y₁ 312 (and of the patterns y₂-y₄). The electronic fuse set 305 thus has 7 electronic fuses. The pattern y₁ 312 indicates that, at time t₁ 310, the first electronic fuse from the left is intact, the second electronic fuse from the left is blown, and the remaining five electronic fuses (the five electronic fuses from the right) are intact. The pattern y₁ 312 encodes a value x₁ 315 of 2 (encoded in binary as “10,” or “0010” in a 4-bit notation).

At time t₂ 320, the electronic fuse set 305 is modified to be set according to a pattern y₂ 322 that is identified as 0110000, to encode a value x₂ 325 of 5 (encoded in binary as “101”). To set the electronic fuse set 305 to the pattern y₂ 322 (from the pattern y₁ 312), an electronic fuse management system blows the third fuse from the left in the electronic fuse set 305. As discussed with respect to the process 200, because the value x₂ 325 is different from the value x₁ 315, the pattern y₂ 322 is determined based on a combination (e.g., XOR) of the value x₂ 325 and a codeword generated from the pattern y₁ 312 (e.g., c(y₁)). The calculation used to generate the pattern y₂ 322 can be written as y₂=c(y₁)⊕x₂.

At time t₃ 330, the electronic fuse set 305 is modified to be set according to a pattern y₃ 332 that is identified as 1111000, to encode a value x₃ 335 of 3 (encoded in binary as “011”). To set the electronic fuse set 305 to the pattern y₃ 332 (from the pattern y₂ 322), an electronic fuse management system blows the first and fourth fuses from the left in the electronic fuse set 305. As discussed with respect to the process 200, because the value x₃ 335 is different from the value x₂ 325, the pattern y₃ 332 is determined based on a combination (e.g., XOR) of the value x₃ 335 and a codeword generated from the pattern y₂ 322 (e.g., c(y₂)). The calculation used to generate the pattern y₃ 332 can be written as y₃=c(y₂)⊕x₃.

At time t₄ 340, the electronic fuse set 305 is modified to be set according to a pattern y₄ 342 that is identified as 1111110, to encode a value x₄ 345 of 7 (encoded in binary as “111”). To set the electronic fuse set 305 to the pattern y₄ 342 (from the pattern y₃ 332), an electronic fuse management system blows the fifth and sixth fuses from the left in the electronic fuse set 305. As discussed with respect to the process 200, because the value x₄ 345 is different from the value x₃ 335, the pattern y₄ 342 is determined based on a combination (e.g., XOR) of the value xx 345 and a codeword generated from the pattern y₃ 332 (e.g., c(y₃)). The calculation 350 used to generate the pattern y₄ 342 can be written as y₄=c(y₃)⊕x₄. The codeword c(y₃) has a value of 1111001, which, when XORed with 111 (the value x₄ 345), results in the pattern y₄ 342 (1111110).

As illustrated in FIG. 3 and described above, the process 300 allows four different values to be written to the 7-bit electronic fuse set 305. The ability to write four different values to an electronic fuse set using other techniques may require, in some examples, a 14-bit electronic fuse set.

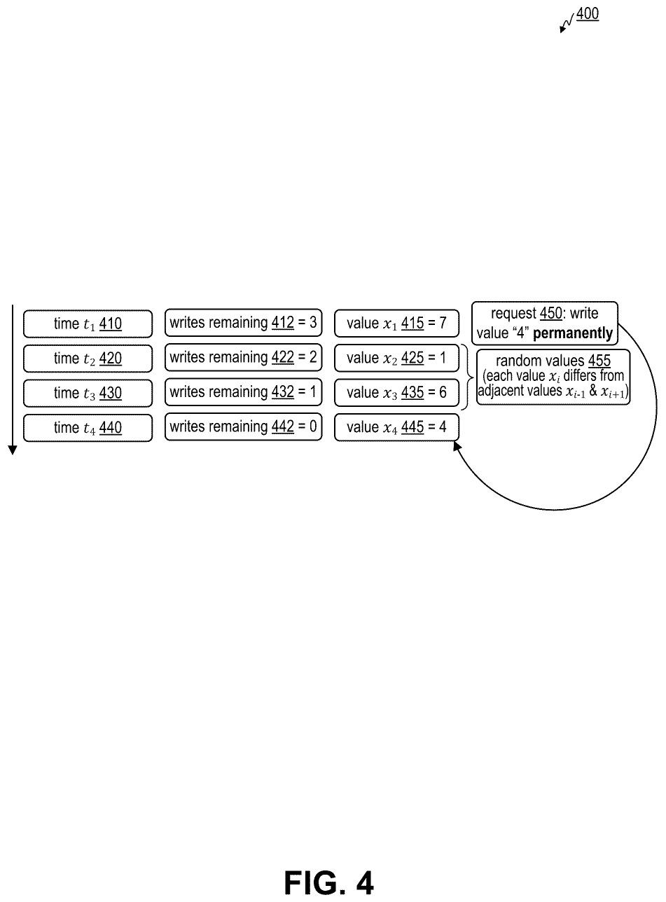

FIG. 4 is a conceptual diagram illustrating a process 400 of writing multiple values to an electronic fuse set to permanently write a value x₄ 445 to the electronic fuse set based on a request. The electronic fuse set of FIG. 4 can be an example of the electronic fuse set 305, the electronic fuse set 260, the set of electronic fuses 140A-140N, the electronic fuse management subsystem 120, or a combination thereof. The patterns that the electronic fuse set is set to at each of the times t₁-t₄ are omitted from FIG. 4, but the values x₁-x₄ written to the electronic fuse set via those patterns are identified in FIG. 4, and the number of possible writes to the electronic fuse set remaining at each of the times t₁-t₄ are also identified in FIG. 4. Time moves forward from time t₁ 410, through time t₂ 420 and time t₃ 430, to time t₄ 440.

At time t₁ 410, the electronic fuse set is set according to a pattern (not shown) that encodes a value x₁ 415 of 7. The number of possible writes remaining 412 to the electronic fuse set at time t₁ 410 is 3.

An electronic fuse management system (e.g., the computing system 100, the electronic fuse management subsystem 120, the electronic fuse management system that performs the process 200, an electronic fuse management system that performs the process 300, or a combination thereof) receives a request 450 to write the value “4” to the electronic fuse set permanently and/or irreversibly. In some examples, electronic fuse management system can receive the request at or before the time t₁ 410, at or before the time t₂ 420, at or before the time t₃ 430, at or before the time t₄ 440, or a combination thereof.

In an illustrative example, the electronic fuse management system receives the request 450 before the time t₂ 420. To fulfill the request, the electronic fuse management system plans to use all of the number of possible writes remaining 412(3) and write the requested value (4) on the last possible write remaining to the electronic fuse set. Based on the comparison 230 (e.g., as in Equation 2), each value xᵢ written to the electronic fuse set is selected by the electronic fuse management system to be different from the previous value written to the electronic fuse set (xᵢ₋₁) and the next value written to the electronic fuse set (xᵢ₊₁), otherwise the electronic fuse set does not actually use up one of the number of possible writes remaining 412 to write the value xᵢ to the electronic fuse set. In some examples, the electronic fuse management system selects values in between the current value and the final value randomly or semi-randomly from the set of possible values that are distinct from the current value, the target value requested by the request 450 (which can also be referred to as the final value), and/or one another.

For instance, if the request 450 is received between time t₁ 410 and time t₂ 420, the current value is the value x₁ 415. Because the number of possible writes remaining 412 is 3 as of the time the request 450 is received, the electronic fuse management system plans to set the value x₄ 445 at the time t₄ 440 to the target value of 4. The electronic fuse management system selects values for the value x₂ 425 at time t₂ 420 and for the value x₃ 435 at time t₃ 430 to be different from the current value (the value x₁ 415 of 7) and the final target value (the value x₄ 445 that is planned to be 4), and one another.

Thus, in the example illustrated in FIG. 4, the electronic fuse management system selects the value x₂ 425 at time t₂ 420 to be 1 and the value x₃ 435 at time t₃ 430 to be 6. Because the value x₂ 425 at time t₂ 420(1) is selected to be different from the value x₁ 415 at time t₁ 410(7), the electronic fuse management system uses up one of the number of possible writes remaining 412, dropping the number of possible writes remaining 422 time t₂ 420 from 3 to 2. Because the value x₃ 435 at time t₃ 430(6) is selected to be different from the value x₂ 425 at time t₂ 420(1), the electronic fuse management system uses up one of the number of possible writes remaining 422, dropping the number of possible writes remaining 432 time t₃ 430 from 2 to 1. Because the value x₃ 435 at time t₃ 430(6) is selected to be different from the value x₄ 435 at time t₄ 440 (the target value 4 requested by the request 450), the electronic fuse management system uses up the final one of the number of possible writes remaining 432, dropping the number of possible writes remaining 442 time t₄ 440) from 1 to 0, ensuring that the electronic fuse set encodes the value x₄ 435 of 4 with the number of possible writes remaining 442 being 0, thus with no further values being possible to write to (to set) the electronic fuse set. Thus, the electronic fuse set is permanently and/or irreversibly set to 4 at and after time t₄ 440 as requested by the request 450.

In some examples, the electronic fuse management system may be able to repeat certain values in the intermediate values between a current value (at the time of receipt of the request 450) and the target value (final value) to be written to the electronic fuse set. For instance, in the process 400, the electronic fuse management system can select the value x₃ 435 at time t₃ 430 to be 7, repeating the value x₁ 415 at time t₁ 410. Because the value x₃ 435 being set to 7 would still make the value x₃ 435 distinct from the values before and after the value x₃ 435—that is, distinct from the value x₂ 425(1) and the value x₄ 445(4)—the value x₃ 435 of 7 would still use up one of the number of possible writes remaining 422 time t₂ 420, dropping the number of possible writes remaining 432 time t₃ 430 from 2 to 1.

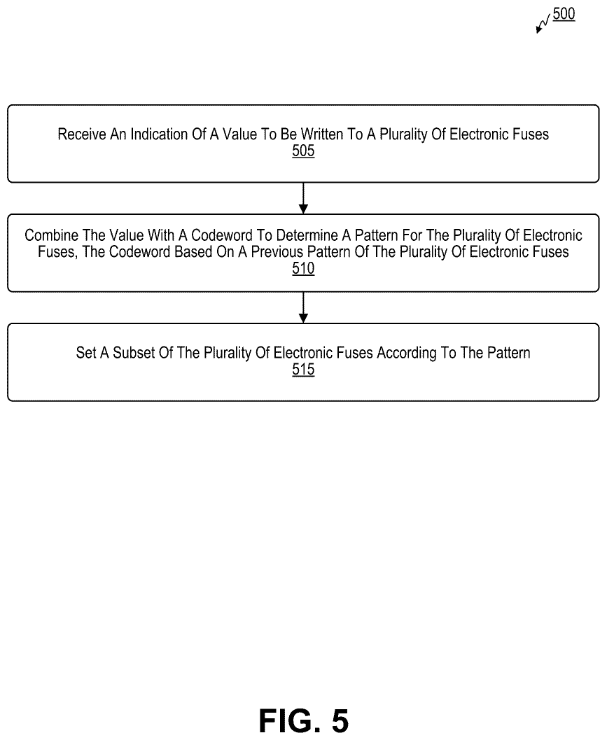

FIG. 5 is a flow diagram illustrating an example of a process 500 for electronic fuse management. The process 500 can be performed by an electronic fuse management system. The electronic fuse management system can include, for instance, the computing system 100, the processor 105, the memory 110, the electronic fuse management subsystem 120, the processor 125, the memory 130, the electronic fuses 140A-140N, the electronic fuses 140A-140E illustrated in the circuitry representation 150, the electronic fuse management system that performs the process 200, a subsystem that executes the interpretation function 220, a subsystem that executes the comparison 230, a subsystem that executes the code function 240, a subsystem that executes the combination function 245, the electronic fuse set 260, a subsystem that executes the tamper detection function 265, the electronic fuse management system that performs the process 300, the electronic fuse set 305, the electronic fuse management system that performs the process 400, the computing system 600, the processor 610, the memory 615, the read-only memory (ROM) 620, the random access memory (RAM) 625, the storage device 630, the output device 635, the communication interface 640, the input device 645, the electronic fuse set 650, a system, an apparatus, a device, a controller, a computer-readable storage medium storing instructions to be executed by a processor, a component or subsystem of any of the previously-listed systems, or a combination thereof.

At operation 505, the electronic fuse management system (or at least one component thereof) is configured to, and can, receive an indication of a value to be written to a plurality of electronic fuses. For instance, in the context of the process 200, the value xᵢ 205 is an example of the value of operation 505. In the context of the calculation 350, the value x₄ 345 is an example of the value of operation 505.

In some examples, the electronic fuse management system includes the plurality of electronic fuses. Examples of the plurality of electronic fuses include the electronic fuses 140A-140N, the electronic fuses 140A-140E illustrated in the circuitry representation 150, the electronic fuse set 260, the electronic fuse set of FIG. 3, the electronic fuse set of FIG. 4, the electronic fuse set 650, or a combination thereof.

In some examples, the value is indicative of a version of a program, such as of an operating system, a firmware, a Basic Input/Output System (BIOS), an application, another type of program, or a combination thereof. For instance, if the program is updated and the version of the program changes to a new version, then the electronic fuse management system can update the value to be indicative of the new version. In some cases, other programs or devices interacting with the program may perform a particular interaction with the program differently depending on the version of the program, and thus may check the plurality of electronic fuses to determine the version of the program before performing the particular interaction with the program to determine how to proceed with the particular interaction.

In some examples, the value is indicative of a cryptographic key to be used for encryption and/or decryption. For instance, in some examples, the electronic fuse management system can store a set of cryptographic keys in a secure memory, and the value can be indicative of which key from the set to use for encryption and/or decryption (e.g., a value n to represent selection of the n^{th} key in the set). In some examples, value can include at least a portion of the cryptographic key. In some examples, the cryptographic key can be a public key, a private key, a symmetric key, an asymmetric key, another type of key, or a combination thereof. For instance, in some cases, the electronic fuse management system receive an indication that a particular cryptographic key that is currently in use has been compromised and therefore should no longer be used, and thus, the electronic fuse management system can modify the plurality of electronic fuses to select a new cryptographic key to use in place of the compromised cryptographic key.

In some examples, the value is indicative of a hardware version (e.g., hardware revision) of an apparatus that performs the process 500 (e.g., the electronic fuse management system or at least one component thereof). For instance, in some examples, a hardware manufacturer can create a new hardware revision of a device, for instance with a different processor or display or other component than a previous hardware revision of the device (e.g., due to discontinuation of the previous component, a defect with the previous component, the new component being cheaper than the previous component, or a combination thereof), and the electronic fuse management system can indicate which hardware version or hardware revision the device uses. In some cases, other devices or programs interacting with the device may perform a particular interaction with the device differently depending on the hardware version or hardware revision of the device, and thus may check the plurality of electronic fuses to determine the hardware version or hardware revision of the device before performing the particular interaction with the device to determine how to proceed with the particular interaction.

In some examples, the value includes a cryptographic message authentication code (MAC). The MAC can serve to verify the validity of the rest the value, and can be used by the a tamper detection function (e.g., the tamper detection function 265) to ensure that the plurality of electronic fuses (e.g., electronic fuse set 260) has not been tampered with, or an error has not occurred.

At operation 510, the electronic fuse management system (or at least one component thereof) is configured to, and can, combine the value with a codeword to determine a pattern for the plurality of electronic fuses. The codeword is based on a previous pattern of the plurality of electronic fuses.

In some examples, at operation 510, the electronic fuse management system (or at least one component thereof) is configured to, and can, determine a pattern for the plurality of electronic fuses based on combining the value with a codeword, the codeword based on a previous pattern of the plurality of electronic fuses.

For instance, in the context of the process 200, the pattern yᵢ₋₁ 210 is an example of the previous pattern of operation 510, the codeword c(yᵢ₋₁) 245 is an example of the codeword of operation 510, the combination function 250 is an example of the combining of operation 510, and the pattern yᵢ 255 is an example of the pattern of operation 510. In the context of the calculation 350, the pattern y₃ 332 (which is equal to 1111000) is an example of the previous pattern of operation 510, the codeword c(y₃) (which is equal to 1111001) is an example of the codeword of operation 510, the XOR in the calculation 350 is an example of the combining of operation 510, and the pattern y₄ 342 (which is equal to 111110) is an example of the pattern of operation 510.

In some examples, combining the value with the codeword (as in operation 510) includes XORing the value with the codeword, for instance as discussed with respect to the combination function 250 and the calculation 350.

In some examples, the electronic fuse management system (or at least one component thereof) is configured to, and can, identify that the value (e.g., value xᵢ 205) differs from a previous value (e.g., value xᵢ₋₁ 225) stored by the previous pattern (e.g., pattern yᵢ₋₁ 210), for instance based on the comparison 230. In some examples, the electronic fuse management system (or at least one component thereof) is configured to, and can, calculate a syndrome (or another type of interpretation function 220) of the previous pattern (e.g., pattern yᵢ₋₁ 210) to determine the previous value (e.g., value xᵢ₋₁ 225).

In some examples, the codeword is a Hamming codeword. In some examples, the electronic fuse management system (or at least one component thereof) is configured to, and can, input the previous pattern into a Hamming codeword function to generate the Hamming codeword. In some examples, the Hamming codeword function is a non-systematic Hamming codeword function. In some examples, the code function 240 is the Hamming codeword function. For instance, the codeword function c( ) of FIG. 3 is a Hamming [7,4,3] codeword function, and the resulting codewords (e.g., c(y₃)) are Hamming [7,4,3] codewords.

In some examples, the codeword is of a specified codeword type, such as a Hamming code, a Sperner code, a Reed-Solomon code, a Goppa code, a Niederreiter code, a Reed-Muller code, a Steane code, a systematic code, a non-systematic code, or a combination thereof. In some examples, the electronic fuse management system (or at least one component thereof) is configured to, and can, input the previous pattern into a codeword function to generate the codeword, with the codeword function being associated with the specified codeword type. Examples of the codeword function include the code function 240 and the codeword function c( ) of FIG. 3.

At operation 515, the electronic fuse management system (or at least one component thereof) is configured to, and can, set a subset of the plurality of electronic fuses according to the pattern.

For instance, in the context of the process 200, a difference between the pattern yᵢ₋₁ 210 and the pattern yᵢ 255 is an example of the subset of operation 515. In the context of the calculation 350, the two instances of the number “1” that are illustrated in FIG. 3 as underlined in the pattern y₄ 342 are an example of the subset of operation 515. These two underlined instances of the number “1” represent two electronic fuses that are set from zero at time t₃ 330 (in the pattern y₃ 332) to one at time t₄ 340 (in the pattern y₄ 342). In the context of the process 300 more broadly, all instances of the number “1” that are illustrated in FIG. 3 as underlined in any of the patterns—including the pattern y₁ 312, the pattern y₂ 322, the pattern y₃ 332, and the pattern y₄ 342—are examples of the subset of operation 515.

In some examples the setting of the subset of the plurality of electronic fuses according to the pattern (as in operation 515) includes setting the subset of the plurality of electronic fuses to at least one dataset according to the pattern. For instance, setting the subset of the plurality of electronic fuses to at least one dataset according to the pattern can include writing specific values to the subset of the plurality of electronic fuses according to the at least one dataset.

In some examples, the electronic fuse management system (or at least one component thereof) is configured to, and can, store at least one forbidden pattern. Detection of the at least one forbidden pattern in the plurality of electronic fuses is configured to indicate tampering (and/or an error) with the plurality of electronic fuses. The electronic fuse management system (or at least one component thereof) can confirm that the pattern (e.g., the pattern yᵢ 255) is distinct from the at least one forbidden pattern (e.g., as part of the tamper detection function 265, to confirm that the electronic fuse set 260 being set to the pattern yᵢ 255 does not represent a tamper attempt or error). In some examples, the electronic fuse management system (or at least one component thereof) can store and/or detect forbidden codewords (e.g., forbidden values for the codeword c(yᵢ₋₁) 245) instead of or in addition to forbidden patterns as part of a tamper detection function 265. In some examples, the electronic fuse management system (or at least one component thereof) can store and/or detect forbidden values (e.g., forbidden values for the value xᵢ 205) instead of or in addition to forbidden patterns as part of a tamper detection function 265.

In some examples, the electronic fuse management system (or at least one component thereof) is configured to, and can, identify a number of possible writes remaining (e.g., number of possible writes remaining 412 to the electronic fuse set at time t₁ 410) for the plurality of electronic fuses, and can set one or more subsets of the plurality of electronic fuses a number of times according to one or more distinct patterns (e.g., as in the setting of the electronic fuse set to the random values 455 at time t₂ 420 and at time t₃ 430 before setting the electronic fuse set to the value x₄ 445 at time t₄ 440) based on the number of possible writes remaining for the plurality of electronic fuses to ensure that the subset of the plurality of electronic fuses being set according to the pattern represents a final possible write (e.g., number of possible writes remaining 442 to the electronic fuse set being zero at time t₄ 440) to the plurality of electronic fuses. For instance, in terms of FIG. 4, the electronic fuse management system can determine that the number of possible writes remaining 412 to the electronic fuse set at time t₁ 410 is 3, can set the electronic fuse set twice to random values 455 (e.g., value x₂ 425 at time t₂ 420 and value x₃ 435 at time t₃ 430) before setting the electronic fuse set to the value x₄ 445 at time t₄ 440 with the number of possible writes remaining 442 to the electronic fuse set being zero at time t₄ 440 to ensure that the setting of the electronic fuse set to the value x₄ 445 represents a final possible write to the electronic fuse set.

In some examples, the electronic fuse management system (or at least one component thereof) is configured to, and can, set an additional subset of the plurality of electronic fuses according to an additional pattern corresponding to an additional value distinct from the value and from a previous value stored by the previous pattern before the setting of the subset of the plurality of electronic fuses according to the pattern. In an illustrative example, the value is the value x₄ 445, the pattern corresponds to the value x₄ 445, the previous value is the value x₁ 415, the pattern corresponds to the value x₁ 415, the additional value includes the value x₂ 425 and/or the value x₃ 435, and the additional pattern corresponds to the value x₂ 425 and/or the value xx 435. In some examples, the electronic fuse management system (or at least one component thereof) selects the additional value at random (e.g., the value x₂ 425 and the value x₃ 435 are selected as random values 455).

In some examples, the setting of the subset of the plurality of electronic fuses according to the pattern (as in operation 515) includes permanently setting the subset of the plurality of electronic fuses according to the pattern. For instance, the electronic fuse management system (or at least one component thereof) can use up a number of possible writes remaining to the electronic fuse set (e.g., the number of possible writes remaining 412 to the electronic fuse set, the number of possible writes remaining 422 to the electronic fuse set, the number of possible writes remaining 432 to the electronic fuse set, or the number of possible writes remaining 442 to the electronic fuse set) to ensure that the number of possible writes remaining to the electronic fuse set is one (e.g., the number of possible writes remaining 432 to the electronic fuse set) before setting the subset of the plurality of electronic fuses according to the pattern, so that the number of possible writes remaining to the electronic fuse set is zero (e.g., the number of possible writes remaining 442 to the electronic fuse set) after setting the subset of the plurality of electronic fuses according to the pattern.

In some examples, the setting of the subset of the plurality of electronic fuses according to the pattern (as in operation 515) includes destructively setting the subset of the plurality of electronic fuses according to the pattern. For instance, destructively setting the subset of the plurality of electronic fuses according to the pattern can include modifying (e.g., blowing) each of the subset of the plurality of electronic fuses to destroy (e.g., blow) at least a portion of each of the subset of the plurality of electronic fuses.

In some examples, the subset of the plurality of electronic fuses is one of the plurality of electronic fuses. For instance, at time t₁ 310, the subset of the plurality of electronic fuses being set from 0 to 1 is only the second bit from the left in the pattern y₁ 312, illustrated with an underline in FIG. 3. Similarly, at time t₂ 320, the subset of the plurality of electronic fuses being set from 0 to 1 is only the third bit from the left in the pattern y₂ 322, illustrated with an underline in FIG. 3. In some examples, the subset of the plurality of electronic fuses includes more than one of the plurality of electronic fuses. For instance, at time t₃ 330, the subset of the plurality of electronic fuses being set from 0 to 1 includes two bits (the first bit and the fourth bit from the left) in the pattern y₃ 332, illustrated with underlines in FIG. 3. Similarly, at time t₄ 340, the subset of the plurality of electronic fuses being set from 0 to 1 includes two bits (the fifth bit and the sixth bit from the left) in the pattern y₄ 342, illustrated with underlines in FIG. 3.

In some examples, the subset of the plurality of electronic fuses represents a difference between the previous pattern and the pattern. For example, the difference between the pattern y₁ 312 and the pattern y₂ 322 is the third bit from the left, which is illustrated as underlined in FIG. 3, and which can be an example of the subset of the plurality of electronic fuses. Similarly, the difference between the pattern y₂ 322 and the pattern y₃ 332 is the first bit from the left and the fourth bit from the left, which are illustrated as underlined in FIG. 3, and which can be an example of the subset of the plurality of electronic fuses. Similarly, the difference between the pattern y₃ 332 and the pattern y₄ 342 is the fifth bit from the left and the sixth bit from the left, which are illustrated as underlined in FIG. 3, and which can be an example of the subset of the plurality of electronic fuses.

The computing device can include any suitable device, such as a mobile device (e.g., a mobile phone), a desktop computing device, a tablet computing device, a wearable device (e.g., a VR headset, an AR headset, AR glasses, a network-connected watch or smartwatch, or other wearable device), a server computer, an autonomous vehicle or computing device of an autonomous vehicle, a robotic device, a television, and/or any other computing device with the resource capabilities to perform the processes described herein, including the process 200, the process 500 and/or other process described herein. In some cases, the computing device or apparatus may include various components, such as one or more input devices, one or more output devices, one or more processors, one or more microprocessors, one or more microcomputers, one or more cameras, one or more sensors, and/or other component(s) that are configured to carry out the steps of processes described herein. In some examples, the computing device may include a display, a network interface configured to communicate and/or receive the data, any combination thereof, and/or other component(s). The network interface may be configured to communicate and/or receive Internet Protocol (IP) based data or other type of data.

The components of the computing device can be implemented in circuitry. For example, the components can include and/or can be implemented using electronic circuits or other electronic hardware, which can include one or more programmable electronic circuits (e.g., microprocessors, graphics processing units (GPUs), digital signal processors (DSPs), central processing units (CPUs), and/or other suitable electronic circuits), and/or can include and/or be implemented using computer software, firmware, or any combination thereof, to perform the various operations described herein.

The process 200, the process 300, the process 400, and the process 500 are illustrated as logical flow diagrams, the operation of which represents a sequence of operations that can be implemented in hardware, computer instructions, or a combination thereof. In the context of computer instructions, the operations represent computer-executable instructions stored on one or more computer-readable storage media that, when executed by one or more processors, perform the recited operations. Generally, computer-executable instructions include routines, programs, objects, components, data structures, and the like that perform particular functions or implement particular data types. The order in which the operations are described is not intended to be construed as a limitation, and any number of the described operations can be combined in any order and/or in parallel to implement the processes.

Additionally, the process 200, the process 300, the process 400, the process 500, and/or other process described herein may be performed under the control of one or more computer systems configured with executable instructions and may be implemented as code (e.g., executable instructions, one or more computer programs, or one or more applications) executing collectively on one or more processors, by hardware, or combinations thereof. As noted above, the code may be stored on a computer-readable or machine-readable storage medium, for example, in the form of a computer program comprising a plurality of instructions executable by one or more processors. The computer-readable or machine-readable storage medium may be non-transitory.

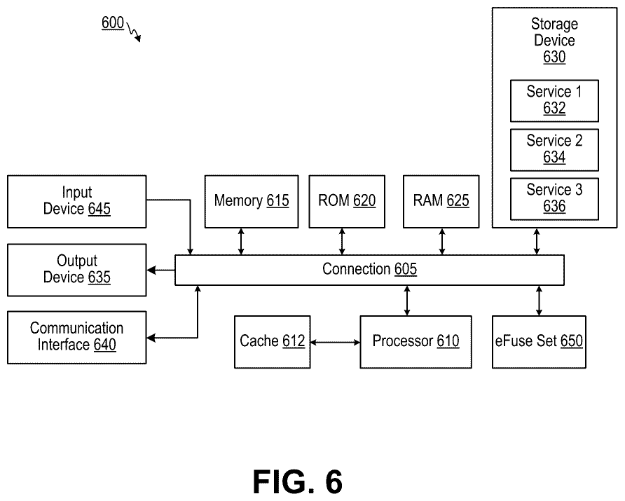

FIG. 6 is a diagram illustrating an example of a system for implementing certain aspects of the present technology. In particular, FIG. 6 illustrates an example of computing system 600, which may be for example any computing device making up internal computing system, a remote computing system, a camera, or any component thereof in which the components of the system are in communication with each other using connection 605. Connection 605 may be a physical connection using a bus, or a direct connection into processor 610, such as in a chipset architecture. Connection 605 may also be a virtual connection, networked connection, or logical connection.

In some embodiments, computing system 600 is a distributed system in which the functions described in this disclosure may be distributed within a datacenter, multiple data centers, a peer network, etc. In some embodiments, one or more of the described system components represents many such components each performing some or all of the function for which the component is described. In some embodiments, the components may be physical or virtual devices.

Example system 600 includes at least one processing unit (CPU or processor) 610 and connection 605 that communicatively couples various system components including system memory 615, such as read-only memory (ROM) 620 and random access memory (RAM) 625 to processor 610. Computing system 600 may include a cache 612 of high-speed memory connected directly with, in close proximity to, or integrated as part of processor 610.

Processor 610 may include any general purpose processor and a hardware service or software service, such as services 632, 634, and 636 stored in storage device 630, configured to control processor 610 as well as a special-purpose processor where software instructions are incorporated into the actual processor design. Processor 610 may essentially be a completely self-contained computing system, containing multiple cores or processors, a bus, memory controller, cache, etc. A multi-core processor may be symmetric or asymmetric.

To enable user interaction, computing system 600 includes an input device 645, which may represent any number of input mechanisms, such as a microphone for speech, a touch-sensitive screen for gesture or graphical input, keyboard, mouse, motion input, speech, etc. Computing system 600 may also include output device 635, which may be one or more of a number of output mechanisms. In some instances, multimodal systems may enable a user to provide multiple types of input/output to communicate with computing system 600.

Computing system 600 may include communications interface 640, which may generally govern and manage the user input and system output. The communication interface may perform or facilitate receipt and/or transmission wired or wireless communications using wired and/or wireless transceivers, including those making use of an audio jack/plug, a microphone jack/plug, a universal serial bus (USB) port/plug, an Apple™ Lightning™ port/plug, an Ethernet port/plug, a fiber optic port/plug, a proprietary wired port/plug, 3G, 4G, 5G and/or other cellular data network wireless signal transfer, a Bluetooth™ wireless signal transfer, a Bluetooth™ low energy (BLE) wireless signal transfer, an IBEACON™ wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof. The communications interface 640 may also include one or more Global Navigation Satellite System (GNSS) receivers or transceivers that are used to determine a location of the computing system 600 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 630 may be a non-volatile and/or non-transitory and/or computer-readable memory device and may be a hard disk or other types of computer readable media which may store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (e.g., Level 1 (L1) cache, Level 2 (L2) cache, Level 3 (L3) cache, Level 4 (L4) cache, Level 5 (L5) cache, or other (L #) cache), resistive random-access memory (RRAM/ReRAM), phase change memory (PCM), spin transfer torque RAM (STT-RAM), another memory chip or cartridge, and/or a combination thereof.

In some examples, the computing system 600 can include an electronic fuse set 650, which can be an example of the electronic fuse management subsystem 120, the set of electronic fuses 140A-140N, the electronic fuse management system that performs the process 200, the electronic fuse set 260, the electronic fuse management system that performs the process 300, the electronic fuse set 305, the electronic fuse management system that performs the process 400, the electronic fuse set of FIG. 4, the plurality of electronic fuses of the process 500, another set of electronic fuses discussed herein, or a combination thereof.

The storage device 630 may include software services, servers, services, etc., that when the code that defines such software is executed by the processor 610, it causes the system to perform a function. In some embodiments, a hardware service that performs a particular function may include the software component stored in a computer-readable medium in connection with the necessary hardware components, such as processor 610, connection 605, output device 635, etc., to carry out the function. The term “computer-readable medium” includes, but is not limited to, portable or non-portable storage devices, optical storage devices, and various other mediums capable of storing, containing, or carrying instruction(s) and/or data. A computer-readable medium may include a non-transitory medium in which data may be stored and that does not include carrier waves and/or transitory electronic signals propagating wirelessly or over wired connections. Examples of a non-transitory medium may include, but are not limited to, a magnetic disk or tape, optical storage media such as compact disk (CD) or digital versatile disk (DVD), flash memory, memory or memory devices. A computer-readable medium may have stored thereon code and/or machine-executable instructions that may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, or the like.

Specific details are provided in the description above to provide a thorough understanding of the embodiments and examples provided herein, but those skilled in the art will recognize that the application is not limited thereto. Thus, while illustrative embodiments of the application have been described in detail herein, it is to be understood that the inventive concepts may be otherwise variously embodied and employed, and that the appended claims are intended to be construed to include such variations, except as limited by the prior art. Various features and aspects of the above-described application may be used individually or jointly. Further, embodiments may be utilized in any number of environments and applications beyond those described herein without departing from the broader scope of the specification. The specification and drawings are, accordingly, to be regarded as illustrative rather than restrictive. For the purposes of illustration, methods were described in a particular order. It should be appreciated that in alternate embodiments, the methods may be performed in a different order than that described.

For clarity of explanation, in some instances the present technology may be presented as including individual functional blocks comprising devices, device components, steps or routines in a method embodied in software, or combinations of hardware and software. Additional components may be used other than those shown in the figures and/or described herein. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Individual embodiments may be described above as a process or method which is depicted as a flowchart, a flow diagram, a data flow diagram, a structure diagram, or a block diagram. Although a flowchart may describe the operations as a sequential process, many of the operations may be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination may correspond to a return of the function to the calling function or the main function.

Processes and methods according to the above-described examples may be implemented using computer-executable instructions that are stored or otherwise available from computer-readable media. Such instructions may include, for example, instructions and data which cause or otherwise configure a general purpose computer, special purpose computer, or a processing device to perform a certain function or group of functions. Portions of computer resources used may be accessible over a network. The computer executable instructions may be, for example, binaries, intermediate format instructions such as assembly language, firmware, source code. Examples of computer-readable media that may be used to store instructions, information used, and/or information created during methods according to described examples include magnetic or optical disks, flash memory, USB devices provided with non-volatile memory, networked storage devices, and so on.

In some embodiments the computer-readable storage devices, mediums, and memories may include a cable or wireless signal containing a bitstream and the like. However, when mentioned, non-transitory computer-readable storage media expressly exclude media such as energy, carrier signals, electromagnetic waves, and signals per sc.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof, in some cases depending in part on the particular application, in part on the desired design, in part on the corresponding technology, etc.

The various illustrative logical blocks, modules, and circuits described in connection with the aspects disclosed herein may be implemented or performed using hardware, software, firmware, middleware, microcode, hardware description languages, or any combination thereof, and may take any of a variety of form factors. When implemented in software, firmware, middleware, or microcode, the program code or code segments to perform the necessary tasks (e.g., a computer-program product) may be stored in a computer-readable or machine-readable medium. A processor(s) may perform the necessary tasks. Examples of form factors include laptops, smart phones, mobile phones, tablet devices or other small form factor personal computers, personal digital assistants, rackmount devices, standalone devices, and so on. Functionality described herein also may be embodied in peripherals or add-in cards. Such functionality may also be implemented on a circuit board among different chips or different processes executing in a single device, by way of further example.

The instructions, media for conveying such instructions, computing resources for executing them, and other structures for supporting such computing resources are example means for providing the functions described in the disclosure.

The techniques described herein may also be implemented in electronic hardware, computer software, firmware, or any combination thereof. Such techniques may be implemented in any of a variety of devices such as general purposes computers, wireless communication device handsets, or integrated circuit devices having multiple uses including application in wireless communication device handsets and other devices. Any features described as modules or components may be implemented together in an integrated logic device or separately as discrete but interoperable logic devices. If implemented in software, the techniques may be realized at least in part by a computer-readable data storage medium comprising program code including instructions that, when executed, performs one or more of the methods, algorithms, and/or operations described above. The computer-readable data storage medium may form part of a computer program product, which may include packaging materials. The computer-readable medium may comprise memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that may be accessed, read, and/or executed by a computer, such as propagated signals or waves.

The program code may be executed by a processor, which may include one or more processors, such as one or more digital signal processors (DSPs), general purpose microprocessors, an application specific integrated circuits (ASICs), field programmable logic arrays (FPGAs), or other equivalent integrated or discrete logic circuitry. Such a processor may be configured to perform any of the techniques described in this disclosure. A general-purpose processor may be a microprocessor; but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Accordingly, the term “processor,” as used herein may refer to any of the foregoing structure, any combination of the foregoing structure, or any other structure or apparatus suitable for implementation of the techniques described herein.

One of ordinary skill will appreciate that the less than (“<”) and greater than (“>”) symbols or terminology used herein may be replaced with less than or equal to (“≤”) and greater than or equal to (“≥”) symbols, respectively, without departing from the scope of this description.

Where components are described as being “configured to” perform certain operations, such configuration may be accomplished, for example, by designing electronic circuits or other hardware to perform the operation, by programming programmable electronic circuits (e.g., microprocessors, or other suitable electronic circuits) to perform the operation, or any combination thereof.

The phrase “coupled to” or “communicatively coupled to” refers to any component that is physically connected to another component either directly or indirectly, and/or any component that is in communication with another component (e.g., connected to the other component over a wired or wireless connection, and/or other suitable communication interface) either directly or indirectly.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, A and B and C, or any duplicate information or data (e.g., A and A, B and B, C and C, A and A and B, and so on), or any other ordering, duplication, or combination of A, B, and C. The language “at least one of” a set and/or “one or more” of a set does not limit the set to the items listed in the set. For example, claim language reciting “at least one of A and B” or “at least one of A or B” may mean A, B, or A and B, and may additionally include items not listed in the set of A and B. The phrases “at least one” and “one or more” are used interchangeably herein.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z; or that multiple processors are each tasked with a certain subset of operations X, Y, and Z such that together the multiple processors perform X, Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

Illustrative aspects of the disclosure include:

Aspect 1. An apparatus for wireless communications, comprising: at least one memory comprising instructions; and at least one processor coupled to the at least one memory and configured to: receive an indication of a value to be written to a plurality of electronic fuses; combine the value with a codeword to determine a pattern for the plurality of electronic fuses, the codeword based on a previous pattern of the plurality of electronic fuses; and set a subset of the plurality of electronic fuses according to the pattern.

Aspect 2. The apparatus of Aspect 1, wherein the at least one processor is configured to: identify that the value differs from a previous value stored by the previous pattern.

Aspect 3. The apparatus of Aspect 2, wherein the at least one processor is configured to: calculate a syndrome of the previous pattern to determine the previous value.

Aspect 4. The apparatus of any of Aspects 1 to 3, wherein the at least one processor is configured to: XOR the value with the codeword to combine the value with the codeword.

Aspect 5. The apparatus of any of Aspects 1 to 4, wherein the codeword is a Hamming codeword.

Aspect 6. The apparatus of Aspect 5, wherein the at least one processor is configured to: input the previous pattern into a Hamming codeword function to generate the Hamming codeword.

Aspect 7. The apparatus of Aspect 6, wherein the Hamming codeword function is a non-systematic Hamming codeword function.

Aspect 8. The apparatus of any of Aspects 1 to 7, wherein the codeword is of a specified codeword type, wherein the specified codeword type is one of a Sperner code, a Reed-Solomon code, a Goppa code, a Niederreiter code, a Reed-Muller code, or a Steane code.

Aspect 9. The apparatus of Aspect 8, wherein the at least one processor is configured to: input the previous pattern into a codeword function to generate the codeword, the codeword function associated with the specified codeword type.

Aspect 10. The apparatus of any of Aspects 1 to 9, wherein the at least one processor is configured to: set the subset of the plurality of electronic fuses to at least one dataset according to the pattern to set the subset of the plurality of electronic fuses according to the pattern.

Aspect 11. The apparatus of any of Aspects 1 to 10, wherein the at least one processor is configured to: store at least one forbidden pattern, wherein detection of the at least one forbidden pattern in the plurality of electronic fuses is configured to indicate tampering with the plurality of electronic fuses; and confirm that the pattern is distinct from the at least one forbidden pattern.

Aspect 12. The apparatus of any of Aspects 1 to 11, wherein the at least one processor is configured to: identify a number of possible writes remaining for the plurality of electronic fuses; and set one or more subsets of the plurality of electronic fuses a number of times according to one or more distinct patterns based on the number of possible writes remaining for the plurality of electronic fuses to ensure that the subset of the plurality of electronic fuses being set according to the pattern represents a final possible write to the plurality of electronic fuses.

Aspect 13. The apparatus of any of Aspects 1 to 12, wherein the at least one processor is configured to: set an additional subset of the plurality of electronic fuses according to an additional pattern corresponding to an additional value distinct from the value and from a previous value stored by the previous pattern before setting the subset of the plurality of electronic fuses according to the pattern.

Aspect 14. The apparatus of Aspect 13, wherein the additional value is selected at random.

Aspect 15. The apparatus of any of Aspects 1 to 14, wherein the at least one processor is configured to: permanently set the subset of the plurality of electronic fuses according to the pattern to set the subset of the plurality of electronic fuses according to the pattern.

Aspect 16. The apparatus of any of Aspects 1 to 15, wherein the at least one processor is configured to: destructively set the subset of the plurality of electronic fuses according to the pattern to set the subset of the plurality of electronic fuses according to the pattern.

Aspect 17. The apparatus of any of Aspects 1 to 16, wherein the value includes a cryptographic message authentication code (MAC).

Aspect 18. The apparatus of any of Aspects 1 to 17, wherein the subset of the plurality of electronic fuses is one of the plurality of electronic fuses.

Aspect 19. The apparatus of any of Aspects 1 to 18, wherein the subset of the plurality of electronic fuses includes more than one of the plurality of electronic fuses.

Aspect 20. The apparatus of any of Aspects 1 to 19, wherein the value is indicative of a version of a program, wherein the program includes at least one of an operating system, a firmware, a Basic Input/Output System (BIOS), or an application.

Aspect 21. The apparatus of any of Aspects 1 to 20, wherein the value is indicative of a cryptographic key to be used for at least one of encryption or decryption.

Aspect 22. The apparatus of any of Aspects 1 to 21, wherein the value is indicative of a hardware version of the apparatus.

Aspect 23. The apparatus of any of Aspects 1 to 22, further comprising: the plurality of electronic fuses.

Aspect 24. The apparatus of any of Aspects 1 to 23, wherein the subset of the plurality of electronic fuses represents a difference between the previous pattern and the pattern.

Aspect 25. A method of electronic fuse management, the method comprising: receiving an indication of a value to be written to a plurality of electronic fuses; determining a pattern for the plurality of electronic fuses based on combining the value with a codeword, the codeword based on a previous pattern of the plurality of electronic fuses; and setting a subset of the plurality of electronic fuses according to the pattern.

Aspect 26. The method of Aspect 25, further comprising: identifying that the value differs from a previous value stored by the previous pattern.

Aspect 27. The method of Aspect 26, further comprising: calculating a syndrome of the previous pattern to determine the previous value.

Aspect 28. The method of any of Aspects 25 to 27, wherein combining the value with the codeword includes XORing the value with the codeword.

Aspect 29. The method of any of Aspects 25 to 28, wherein the codeword is a Hamming codeword.

Aspect 30. The method of Aspect 29, further comprising: inputting the previous pattern into a Hamming codeword function to generate the Hamming codeword.

Aspect 31. The method of Aspect 30, wherein the Hamming codeword function is a non-systematic Hamming codeword function.

Aspect 32. The method of any of Aspects 25 to 31, wherein the codeword is of a specified codeword type, wherein the specified codeword type is one of a Sperner code, a Reed-Solomon code, a Goppa code, a Niederreiter code, a Reed-Muller code, or a Steane code.

Aspect 33. The method of Aspect 32, further comprising: inputting the previous pattern into a codeword function to generate the codeword, the codeword function associated with the specified codeword type.

Aspect 34. The method of any of Aspects 25 to 33, wherein the setting of the subset of the plurality of electronic fuses according to the pattern includes setting the subset of the plurality of electronic fuses to at least one dataset according to the pattern.

Aspect 35. The method of any of Aspects 25 to 34, further comprising: storing at least one forbidden pattern, wherein detection of the at least one forbidden pattern in the plurality of electronic fuses is configured to indicate tampering with the plurality of electronic fuses; and confirming that the pattern is distinct from the at least one forbidden pattern.

Aspect 36. The method of any of Aspects 25 to 35, further comprising: identifying a number of possible writes remaining for the plurality of electronic fuses; and setting one or more subsets of the plurality of electronic fuses a number of times according to one or more distinct patterns based on the number of possible writes remaining for the plurality of electronic fuses to ensure that the subset of the plurality of electronic fuses being set according to the pattern represents a final possible write to the plurality of electronic fuses.

Aspect 37. The method of any of Aspects 25 to 36, further comprising: setting an additional subset of the plurality of electronic fuses according to an additional pattern corresponding to an additional value distinct from the value and from a previous value stored by the previous pattern before the setting of the subset of the plurality of electronic fuses according to the pattern.

Aspect 38. The method of Aspect 37, wherein the additional value is selected at random.

Aspect 39. The method of any of Aspects 25 to 38, wherein the setting of the subset of the plurality of electronic fuses according to the pattern includes permanently setting the subset of the plurality of electronic fuses according to the pattern.

Aspect 40. The method of any of Aspects 25 to 39, wherein the setting of the subset of the plurality of electronic fuses according to the pattern includes destructively setting the subset of the plurality of electronic fuses according to the pattern.

Aspect 41. The method of any of Aspects 25 to 40, wherein the value includes a cryptographic message authentication code (MAC).

Aspect 42. The method of any of Aspects 25 to 41, wherein the subset of the plurality of electronic fuses is one of the plurality of electronic fuses.

Aspect 43. The method of any of Aspects 25 to 42, wherein the subset of the plurality of electronic fuses includes more than one of the plurality of electronic fuses.

Aspect 44. The method of any of Aspects 25 to 43, wherein the value is indicative of a version of a program, wherein the program includes at least one of an operating system, a firmware, a Basic Input/Output System (BIOS), or an application.

Aspect 45. The method of any of Aspects 25 to 44, wherein the value is indicative of a cryptographic key to be used for at least one of encryption or decryption.

Aspect 46. The method of any of Aspects 25 to 45, wherein the value is indicative of a hardware version of an apparatus that performs the method.

Aspect 47. The method of any of Aspects 25 to 46, wherein the method is performed using an apparatus that includes the plurality of electronic fuses.

Aspect 48. The method of any of Aspects 25 to 47, wherein the subset of the plurality of electronic fuses represents a difference between the previous pattern and the pattern.

Aspect 49. A non-transitory computer-readable medium having stored thereon instructions that, when executed by at least one processor, cause the at least one processor to perform operations according to any of Aspects 1 to 48.

Aspect 50. An apparatus for wireless communications, comprising one or more means for performing operations according to any of Aspects 1 to 48.

What is claimed is:

1. An apparatus for electronic fuse management, the apparatus comprising:
at least one memory; and
at least one processor coupled to the at least one memory and configured to:
receive an indication of a value to be written to a plurality of electronic fuses;
combine the value with a codeword to determine a pattern for the plurality of electronic fuses, the codeword based on a previous pattern of the plurality of electronic fuses; and
set a subset of the plurality of electronic fuses according to the pattern.

2. The apparatus of claim 1, wherein the at least one processor is configured to:
identify that the value differs from a previous value stored by the previous pattern.

3. The apparatus of claim 2, wherein the at least one processor is configured to:
calculate a syndrome of the previous pattern to determine the previous value.

4. The apparatus of claim 1, wherein the at least one processor is configured to:
XOR the value with the codeword to combine the value with the codeword.

5. The apparatus of claim 1, wherein the codeword is a Hamming codeword.

6. The apparatus of claim 5, wherein the at least one processor is configured to:
input the previous pattern into a Hamming codeword function to generate the Hamming codeword.

7. The apparatus of claim 6, wherein the Hamming codeword function is a non-systematic Hamming codeword function.

8. The apparatus of claim 1, wherein the codeword is of a specified codeword type, wherein the specified codeword type is one of a Sperner code, a Reed-Solomon code, a Goppa code, a Niederreiter code, a Reed-Muller code, or a Steane code.

9. The apparatus of claim 8, wherein the at least one processor is configured to:
input the previous pattern into a codeword function to generate the codeword, the codeword function associated with the specified codeword type.

10. The apparatus of claim 1, wherein the at least one processor is configured to:
set the subset of the plurality of electronic fuses to at least one dataset according to the pattern to set the subset of the plurality of electronic fuses according to the pattern.

11. The apparatus of claim 1, wherein the at least one processor is configured to:
store at least one forbidden pattern, wherein detection of the at least one forbidden pattern in the plurality of electronic fuses is configured to indicate tampering with the plurality of electronic fuses; and
confirm that the pattern is distinct from the at least one forbidden pattern.

12. The apparatus of claim 1, wherein the at least one processor is configured to:
identify a number of possible writes remaining for the plurality of electronic fuses; and
set one or more subsets of the plurality of electronic fuses a number of times according to one or more distinct patterns based on the number of possible writes remaining for the plurality of electronic fuses to ensure that the subset of the plurality of electronic fuses being set according to the pattern represents a final possible write to the plurality of electronic fuses.

13. The apparatus of claim 1, wherein the at least one processor is configured to:
set an additional subset of the plurality of electronic fuses according to an additional pattern corresponding to an additional value distinct from the value and from a previous value stored by the previous pattern before setting the subset of the plurality of electronic fuses according to the pattern.

14. The apparatus of claim 13, wherein the additional value is selected at random.

15. The apparatus of claim 1, wherein the at least one processor is configured to:
permanently set the subset of the plurality of electronic fuses according to the pattern to set the subset of the plurality of electronic fuses according to the pattern.

16. The apparatus of claim 1, wherein the at least one processor is configured to:
destructively set the subset of the plurality of electronic fuses according to the pattern to set the subset of the plurality of electronic fuses according to the pattern.

17. The apparatus of claim 1, wherein the value includes a cryptographic message authentication code (MAC).

18. The apparatus of claim 1, wherein the subset of the plurality of electronic fuses is one of the plurality of electronic fuses.

19. The apparatus of claim 1, wherein the subset of the plurality of electronic fuses includes more than one of the plurality of electronic fuses.

20. The apparatus of claim 1, wherein the value is indicative of a version of a program, wherein the program includes at least one of an operating system, a firmware, a Basic Input/Output System (BIOS), or an application.

21. The apparatus of claim 1, wherein the value is indicative of a cryptographic key to be used for at least one of encryption or decryption.

22. The apparatus of claim 1, wherein the value is indicative of a hardware version of the apparatus.

23. The apparatus of claim 1, further comprising:
the plurality of electronic fuses.

24. The apparatus of claim 1, wherein the subset of the plurality of electronic fuses represents a difference between the previous pattern and the pattern.

25. A method of electronic fuse management, the method comprising:
receiving an indication of a value to be written to a plurality of electronic fuses;
determining a pattern for the plurality of electronic fuses based on combining the value with a codeword, the codeword based on a previous pattern of the plurality of electronic fuses; and
setting a subset of the plurality of electronic fuses according to the pattern.

26. The method of claim 25, further comprising:
identifying that the value differs from a previous value stored by the previous pattern.

27. The method of claim 25, wherein combining the value with the codeword includes XORing the value with the codeword.

28. The method of claim 25, wherein the codeword is a Hamming codeword.

29. The method of claim 25, further comprising:
storing at least one forbidden pattern, wherein detection of the at least one forbidden pattern in the plurality of electronic fuses is configured to indicate tampering with the plurality of electronic fuses; and
confirming that the pattern is distinct from the at least one forbidden pattern.

30. The method of claim 25, further comprising:
identifying a number of possible writes remaining for the plurality of electronic fuses; and
setting one or more subsets of the plurality of electronic fuses a number of times according to one or more distinct patterns based on the number of possible writes remaining for the plurality of electronic fuses to ensure that the subset of the plurality of electronic fuses being set according to the pattern represents a final possible write to the plurality of electronic fuses.
